(19) United States
(12) Patent Application Publication
(10) Pub. No.: US 2026/0186059 A1
(43) Pub. Date: Jul. 2, 2026

(54) BATTERY MANAGEMENT DEVICE AND METHOD

(71) Applicants: HYUNDAI MOTOR COMPANY, Seoul (KR); KIA CORPORATION, Seoul (KR); UIF (University Industry Foundation), Yonsei University, Seoul (KR)

(72) Inventors: Woo Ju Lee, Hwaseong-si (KR); Min Joo Kim, Hwaseong-si (KR); Jung Il Choi, Goyang-si (KR); Seong Yoon Kim, Incheon (KR); Sang Hyun Kim, Seoul (KR); Jin Ho Ha, Seoul (KR); Kyeong Eun Cho, Seoul (KR)

(73) Assignees: HYUNDAI MOTOR COMPANY, Seoul (KR); KIA CORPORATION, Seoul (KR); UIF (University Industry Foundation), Yonsei University, Seoul (KR)

(21) Appl. No.: 19/229,928

(22) Filed: Jun. 5, 2025

(30) Foreign Application Priority Data
Dec. 30, 2024 (KR) 10-2024-0201082

(51) Int. Cl. G01R 31/367; B60L 58/16; G01R 31/3842; G01R 31/389; G01R 31/392

(52) U.S. Cl. CPC G01R 31/367; B60L 58/16; G01R 31/3842; G01R 31/389; G01R 31/392; B60L 2240/545; B60L 2240/547; B60L 2240/549

(57) ABSTRACT

A battery management device includes a memory that stores a battery model and an algorithm, and a processor that obtains state information of battery using the battery model. The processor obtains a predicted voltage of the battery based on the battery model, determines a voltage error between a measured voltage of the battery and the predicted voltage, and updates the battery model by resetting a parameter of the battery model based on the voltage error exceeding a first threshold.

### CROSS-REFERENCE TO RELATED APPLICATION

This application claims the benefit of and priority to Korean Patent Application No. 10-2024-0201082, filed on Dec. 30, 2024, the entire contents of which are hereby incorporated herein by reference.

### TECHNICAL FIELD

The present disclosure relates to a battery management device and method, and more particularly to a technique for more accurately determining state information of a battery.

### BACKGROUND

Batteries are increasingly utilized in various electronic devices, and in recent years, the use of batteries has been increasing with the advent of electric vehicles, such as electric vehicles or hybrid vehicles.

For efficiency and reliability reasons, it is recommended that batteries in electric vehicles be replaced before they become severely degraded. Also, the charging and discharging capacity of the battery may be adjusted based on the degree of battery degradation.

Therefore, battery state information, including battery degradation, may be determined and used to properly manage the battery. The degree of battery deterioration may be identified through the state of health (SOH) of the battery.

As such, a battery system may determine the state information of the battery to operate the battery efficiently, and technologies have been proposed to inform the user of the state information of the battery.

However, the battery state information may be subject to errors depending on the driving pattern of the vehicle in which the battery is installed. The general battery model for determining the battery state information typically does not properly reflect the errors in the battery state information caused by the driving pattern of the vehicle.

To more accurately determine the state of the battery, impedance analysis using electrochemical spectroscopy may be used. However, this method is difficult to apply to automotive batteries because it requires separate experimental equipment and requires a long experimental time.

There is also a way to use an equivalent circuit model to understand the characteristics of automotive batteries. However, battery models based on equivalent circuit models have the disadvantage of low accuracy because they do not reflect the internal physical phenomena of the battery.

The matters described in this Background section are only intended to enhance understanding of the background of the present disclosure. Therefore, the Background section may contain information that does not form prior art that is already known to those having ordinary skill in the art to which the present disclosure pertains.

### SUMMARY

The present disclosure has been made to solve the above-mentioned problems occurring in the prior art while advantages achieved by the prior art are maintained intact.

Aspects of the present disclosure provide a battery management device and method for obtaining state information of a battery mounted in a vehicle in a simple yet more accurate manner.

Aspects of the present disclosure provide a battery management device and method that may more accurately acquire state information of a battery reflecting the conditions under which the battery is operated.

The technical problems to be solved by the present disclosure are not limited to the aforementioned problems. Other technical problems not mentioned herein should be more clearly understood from the following description by those having ordinary skill in the art to which the present disclosure pertains.

According to an aspect of the present disclosure, a battery management device is provided. The battery management device includes a memory configured to store a battery model and an algorithm, and a processor configured to obtain state information of a battery using the battery model. The processor is configured to obtain a predicted voltage of the battery based on the battery model, determine a voltage error between a measured voltage of the battery and the predicted voltage, and update the battery model by resetting a parameter of the battery model based on determining that the voltage error satisfies a threshold condition.

In an embodiment, the parameter may be set based on an electrochemical basis to represent internal state information of the battery.

In an embodiment, the processor may be configured to obtain a measured current of the battery and determine the predicted voltage of the battery by inputting the measured current into the battery model.

In an embodiment, the processor may be configured to collect the measured current obtained during a driving period of a vehicle equipped with the battery.

In an embodiment, the processor may be configured to determine the voltage error based on the measured voltage acquired at the same timing as the measured current.

In an embodiment, the processor may be configured to determine the voltage error using a root mean square error obtained based on voltage differences between “n” measured voltages and “n” predicted voltages, where n is a natural number greater than or equal to two.

In an embodiment, the processor may be configured to reset the parameter to reduce the voltage error between the measured voltage and the predicted voltage.

In an embodiment, the processor may be configured to generate a new parameter, obtain a modified predicted voltage based on the battery model with the new parameter applied, and reset the parameter such that a voltage error between the measured voltage and the modified predicted voltage falls within a threshold range.

In an embodiment, the processor may be configured to reset at least one of an internal resistance, a diffusion coefficient, a reaction rate constant, or a porosity among the parameters.

In an embodiment, the processor may be configured to determine at least one of a State Of Health of the battery or a loss of active material using the battery model.

According to another aspect of the present disclosure, a battery: management method is provided. The battery management method includes obtaining a predicted voltage of a battery based on a battery model, determining a voltage error between a measured voltage of the battery and the predicted voltage, and updating the battery model by resetting a parameter of the battery model based on determining that the voltage satisfies a threshold condition.

In an embodiment, the parameter may be set based on an electrochemical basis to represent internal state information of the battery.

In an embodiment, determining the predicted voltage may include obtaining a measured current of the battery, and inputting the measured current into the battery model.

In an embodiment, obtaining the measured current may be performed during a driving period of a vehicle equipped with the battery.

In an embodiment, determining the voltage error may include using the measured voltage acquired at the same timing as the measured current.

In an embodiment, determining the voltage error may include determining a root mean square error based on voltage differences between “n” measured voltages and “n” predicted voltages, where n is a natural number greater than or equal to two.

In an embodiment, resetting the parameter may include resetting the parameter to reduce the voltage error between the measured voltage and the predicted voltage.

In an embodiment, resetting the parameter may include generating a new parameter, obtaining a modified predicted voltage based on the battery model with the new parameter applied, and comparing a voltage error between the measured voltage and the modified predicted voltage with a threshold range.

According to yet another aspect of the present disclosure, a battery management server is provided. The battery management server includes a database that stores a battery model and an algorithm, and a processor configured to obtains state information of a battery mounted on a vehicle using the battery model. The processor is configured to collect measured voltage and measured current of the battery obtained during a driving period of the vehicle, obtain a predicted voltage of the battery based on the battery model, determine a voltage error between the measured voltage and the predicted voltage, and update the battery model by resetting a parameter of the battery model based on determining that the voltage error satisfies a threshold condition.

In an embodiment, the processor may be configured to generate battery state information to include at least one of a State Of Health of the battery or a loss of active material using the battery model, and transmit the battery state information to the vehicle via a communication device.

### BRIEF DESCRIPTION OF THE DRAWINGS

The above and other objects, features, and advantages of the present disclosure should be more apparent from the following detailed description taken in conjunction with the accompanying drawings, in which:

FIG. 1 is a block diagram illustrating a configuration of a battery management device according to an embodiment of the present disclosure;

FIG. 2 is a flowchart for describing a battery management method according to an embodiment of the present disclosure;

FIG. 3 illustrates a user interface according to an embodiment of the present disclosure;

FIG. 4 is a diagram for describing a battery management system according to another embodiment of the present disclosure;

FIG. 5 is a flowchart for describing a method for acquiring driving data according to an embodiment of the present disclosure;

FIG. 6 is a diagram for describing a process for determining the conformity of parameters according to an embodiment of the present disclosure;

FIG. 7 is a flowchart for describing a process for resetting parameters according to an embodiment of the present disclosure; and

FIG. 8 is a diagram illustrating a computing system according to an embodiment of the present disclosure.

### DETAILED DESCRIPTION

Hereinafter, embodiments of the present disclosure are described in detail with reference to the accompanying drawings. In adding the reference numerals to the components of the drawings, it should be noted that the identical or equivalent components are designated by the identical reference numerals even when the components are displayed on different drawings. Further, in describing the embodiment of the present disclosure, where it was determined that a detailed description of well-known features or functions would unnecessarily obscure the gist of the present disclosure, the detailed description thereof has been omitted.

In the following description, terms such as first, second, “A”, “B”, (a), (b), and the like may be used. These terms are merely intended to distinguish one component from another component. The terms do not limit the nature, sequence, or order of the constituent components. Unless otherwise defined, all terms used herein, including technical or scientific terms, have the meanings as those generally understood by those having ordinary skill in the art to which the present disclosure pertains. Such terms as those defined in a generally used dictionary should be interpreted as having meanings equivalent to the contextual meanings in the relevant field of art, and should not be interpreted as having ideal or excessively formal meanings unless clearly defined as having such in the present application.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function. Each component, controller, device, element, apparatus, unit, and the like may separately embody or be included with a processor and a memory, such as a non-transitory computer readable media, as part of the apparatus.

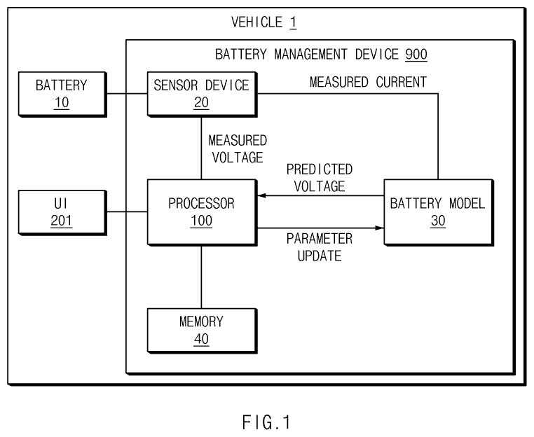

Hereinafter, embodiments of the present disclosure are described in detail with reference to FIGS. 1-8.

FIG. 1 is a block diagram illustrating a configuration of a battery management device according to an embodiment of the present disclosure.

Referring to FIG. 1, a battery management device 900 according to an embodiment of the present disclosure may obtain state information of a battery 10 based on sensing data such as current, voltage, temperature, etc. of the battery 10.

The battery 10 and the battery management device 900 may be mounted within a vehicle 1.

The battery 10 may be for providing voltage to loads mounted on the vehicle 1. The loads may be electrical components of the vehicle 1, DC-DC converters, motors that drive wheels, etc.

The battery management device 900 may include a sensor device 20, a battery model 30, a memory 40, and a processor 100.

The sensor device 20 may include sensors for measuring voltage, current, and temperature, etc. of the battery 10. The sensor device 20 may acquire sensing data using the sensors. The sensing data may be used to acquire a measured voltage, a measured current, a measured temperature, or the like of the battery 10. The battery model 30 may be for acquiring state information of the battery 10. The state information of the battery 10 may include a State Of Health (SOH) of the battery 10, active material loss information, and/or the like.

The battery model 30 may be an electrochemical model. The battery model 30 according to embodiments of the present disclosure may be generated based on electrochemical degradation modeling, that may reflect the internal state of the battery 10, thereby more accurately obtaining the state information of the battery 10. In an embodiment, the battery model 30 may be stored in the memory 40.

The memory 40 may be used to store algorithms for the operation of the processor 100. The memory 49 may be implemented with a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a Dynamic Random Access Memory (DRAM), a Synchronous Dynamic Random Access Memory (SDRAM), a Double Date Rate-SDRAM (DDR-SDRAM), or other similar types of memory.

The processor 100 may obtain a predicted voltage of the battery 10 using the battery model 30 and may update internal variables of the battery model 30 based on the predicted voltage and the measured voltage acquired by the sensor device 20. The processor 100 may more accurately obtain the state information of the battery 10 using the updated internal variables of the battery model 30. According to an embodiment of the present disclosure, the processor 100 may reset the parameters of the battery model 30 based on sensing data acquired during a period of time when the vehicle 1 is driving.

In an embodiment, the processor 100 may acquire driving data that includes sensing data for each driving period.

The driving data may include a usage time of the vehicle 1 and a mileage of the vehicle 1. The usage time of the vehicle 1 may include a period of time from a time when the battery of the vehicle 1 is used to a time when the driving data is acquired. The mileage of the vehicle 1 may include a cumulative mileage of the vehicle. Further, the driving data may include parking data acquired while the vehicle is parked. The parking data may include the time the vehicle 1 was parked, the temperature during a parking period, and/or the SOC during the parking. For example, the driving data may include charging data including a charge output (C-rate) for charging (or discharging) the battery, and/or charging temperature.

The processor 100 may acquire the driving data via the sensors during one driving cycle that may include a time when the vehicle 1 starts driving and a time when the vehicle 1 ends driving. Thus, the driving data may correspond to one driving cycle.

The processor 100 may update the battery model 30 based on the driving data obtained during the driving period to build the battery model 30 that reflects the various conditions under which the vehicle 1 was actually driven.

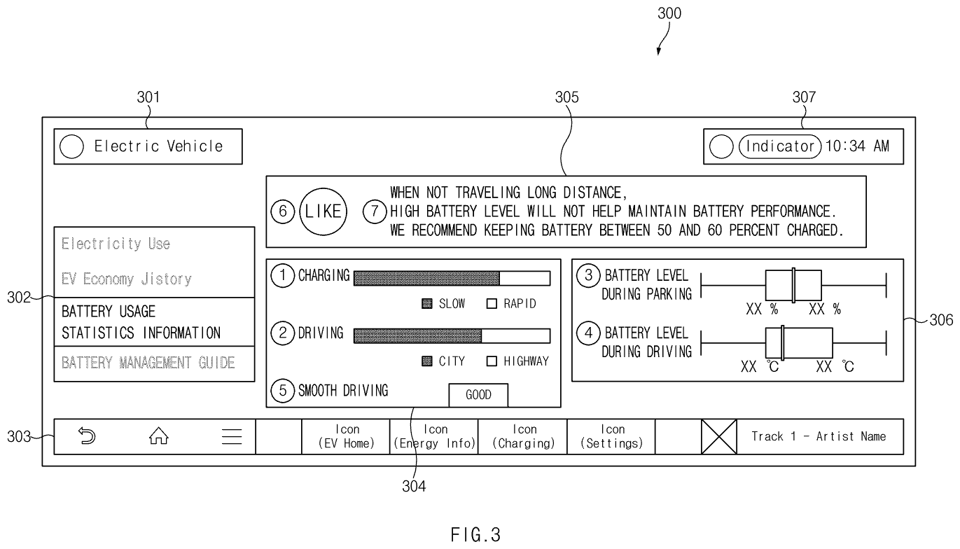

The operation of the processor 100 to update internal variables of the battery model 30, according to an embodiment, is described in more detail below with reference to FIG. 3.

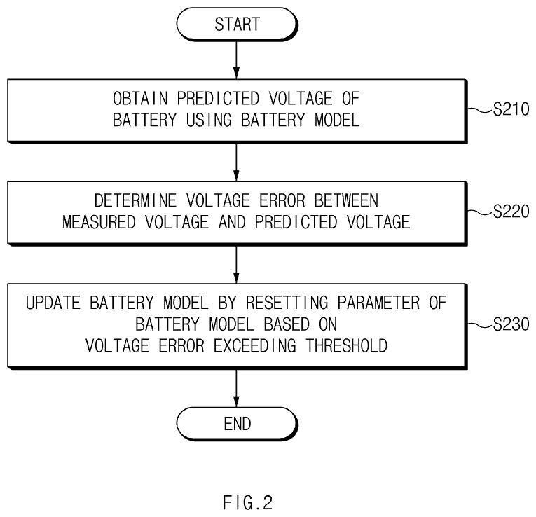

FIG. 2 is a flowchart for describing a battery management method according to an embodiment of the present disclosure. FIG. 2 shows a process performed by the processor 100 shown in FIG. 1.

In an operation S210, the processor 100 may obtain a predicted voltage using the battery model 30.

The battery model 30 may be for obtaining state information of the battery 10 using preset parameters.

The parameters of the battery model 30 may be set on an electrochemical basis to represent internal state information of the battery 10. For example, the battery model 30 may be a Pseudo Tow-Dimensional Model (P2D Model).

The processor 100 may input a measured current into the battery model 30 to obtain a predicted voltage. The measured current may refer to a current value of the battery 10 obtained via the sensor device 20.

The processor 100 may collect “n” (where n is a natural number greater than or equal to 2) measured currents from the sensor device 20 and obtain “n” predicted voltages based on the measured currents.

To obtain the predicted voltage, the processor 100 may utilize not only the measured current but also the measured temperature of the battery 10.

In an operation S220, the processor 100 may determine a voltage error between the measured voltage and the predicted voltage of the battery 10.

The measured voltage may refer to the voltage value of the battery 10 obtained through the sensor device 20.

The processor 100 may collect “n” measured voltages from the sensor device 20. Based on the “n” measured voltages and the “n” predicted voltages, the processor 100 may determine the voltage error.

To determine the voltage error between the measured voltage of the battery 10 and the predicted voltage, the processor 100 may utilize a first objective function. The first objective function may use the Root Mean Square Error (RMSE) between the “n” measured voltages and the “n” predicted voltages, for example.

In an operation S230, based on a determination that the voltage error satisfies a threshold condition (e.g., exceeds a threshold value), the parameters of the battery model may be reset.

The processor 100 may reset the parameters of the battery model using a second objective function. The second objective function may be identical to the first objective function. For example, the processor 100 may reset the parameters using the Root Mean Square Error between the “n” measured voltages and the “n” predicted voltages.

The processor 100 may repeatedly perform a process of setting new parameters and comparing the result value of the second objective function with a threshold based on the result value of the second objective function being less than the threshold. The new parameters may be generated randomly. When the result value of the second objective function obtained by applying the new parameters is less than the threshold, the processor 100 may terminate the process of resetting parameters. Then, the processor 100 may update the battery model 30 by applying the parameters that make the result value of the second objective function fall below the threshold.

Alternatively, the processor 100 may reset the parameters using methods other than the Root Mean Square Error.

The processor 100 may acquire the state information of the battery 10 based on the updated battery model 30.

According to an embodiment, the processor 100 may determine the State of Health (SOH) of the battery 10 using the (e.g., updated) battery model 30.

Additionally, the processor 100 may determine the loss of active material of the battery 10 using the (e.g., updated) battery model 30.

The processor 100 may output the state information of the battery 10 through a user interface (UI) 201 of the vehicle 1. The state information output through the UI 201 may alert a user that the battery 10 should be replaced in case that the battery 10 has degraded to a sufficient degree, for example.

The processor 100 may additionally, or alternatively, manage the battery 10 based on the state information of the battery 10. For example, the processor 100 may cause the charging and discharging capacity of the battery 10 to be adjusted based on the degree of battery degradation.

FIG. 3 illustrates a user interface according to an embodiment of the present disclosure.

Referring to FIG. 3, a user interface 300 may be implemented as a display that displays a first screen 301 to a seventh screen 307. The display may receive a touch input from a user.

The processor 100 may generate image data to configure the first screen 301 to the seventh screen 307 based on the state information of the battery 10.

The first screen 301 may be a screen for displaying identification information of the vehicle 1.

The second screen 302 may be a screen for displaying a menu for changing a display screen type. When battery usage statistics information is selected based on a touch input from the user, the processor 100 may display battery usage statistics information via screens from the third screen 303 to the seventh screen 307. For example, the processor 100 may display the state information of the battery 10 via the sixth screen 306.

The third screen 303 may be a screen for displaying information such as the previous page icon, a home page icon, a menu, an energy information icon, a charging information icon, a settings icon, and currently playing content.

The fourth screen 304 may be a screen for displaying the ratio of battery charging types, the ratio of driving types, the ratio of driving styles, and/or the like.

The fifth screen 305 may be a screen for displaying battery state notifications and battery management guidance.

The sixth screen 306 may be a screen for displaying battery level while parked, battery temperature while driving, and battery aging state.

The seventh screen 307 may be a screen for displaying a search function, time information, and/or the like.

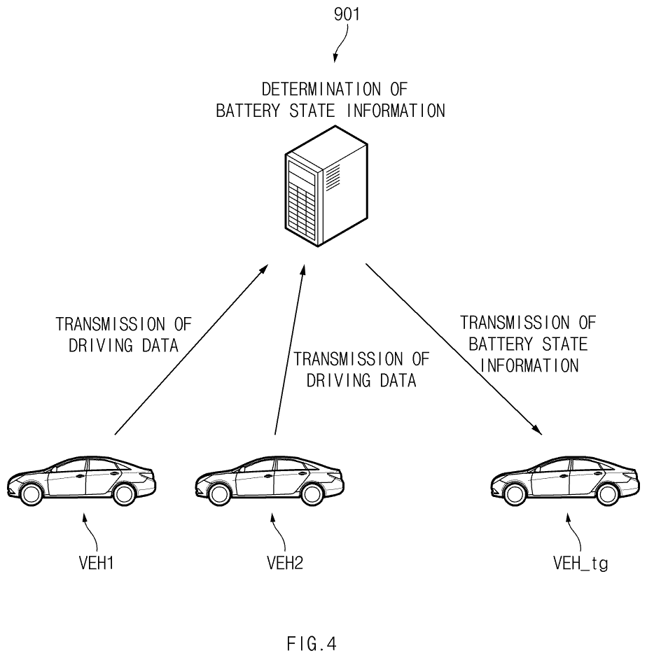

FIG. 4 is a diagram for describing a battery management system according to another embodiment of the present disclosure.

Referring to FIG. 4, a battery management system according to an embodiment of the present disclosure may include a server 901 connected to information collecting vehicles VEH1 and VEH2 and a target vehicle VEH_tg via a network.

The server 901 may transmit and receive wireless signals with at least one of a base station, an external terminal, and a center on a mobile communication network established in accordance with technical standards or communication methods for mobile communications. For example, mobile communication means may be implemented based on Global System for Mobile communication (GSM), Code Division Multi Access (CDMA), Code Division Multi Access 2000 (CDMA 2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), or LTE-A (Long Term Evolution-Advanced).

The information collecting vehicles VEH1 and VEH2 may acquire driving data at predetermined time intervals. For example, the information collecting vehicles VEH1 and VEH2 may obtain a measured voltage, a measured current, and a measured temperature of the battery 10 at regular time intervals and generate driving data. The information collecting vehicles VEH1 and VEH2 may transmit the driving data to the server 901.

The server 901 may include a database (not shown) and a processor (not shown). The database may store a battery model, and the processor of the server 901 may obtain the state information of the battery 10 using the battery model. The server 901 may transmit the state information of the battery 10 to the target vehicle VEH_tg.

The information collecting vehicles VEH1 and VEH2 and the target vehicle VEH_tg may be the same vehicle 1.

In an embodiment, the server 901 may learn from the driving data collected by the information collecting vehicles VEH1 and VEH2 and determine, as the target vehicle VEH_tg, a vehicle having similar driving data to the information collecting vehicles VEH1 and VEH2. Accordingly, the server 901 may update the battery model even for vehicles that have not collected driving data.

Additionally, the server 901 may receive driving data from the information collecting vehicles VEH1 and VEH2 and may update the parameters of the battery model 30 based on the driving data.

In an embodiment, the server 901 may receive driving data at predetermined time intervals.

When the server 901 has collected a predefined number (n) of pieces of driving data, the server 901 may obtain a predicted voltage by applying the collected “n” pieces of driving data to the battery model 30. The server 901 may reset the parameters of the battery model 30 based on determining that the difference between the predicted voltage obtained using the battery model 30 and the measured voltage included in the driving data satisfies a threshold condition (e.g., exceeds a threshold value).

The server 901 may update the battery model 30 based on the reset parameters.

The detailed procedure of the battery management method according to embodiments of the present disclosure is described below.

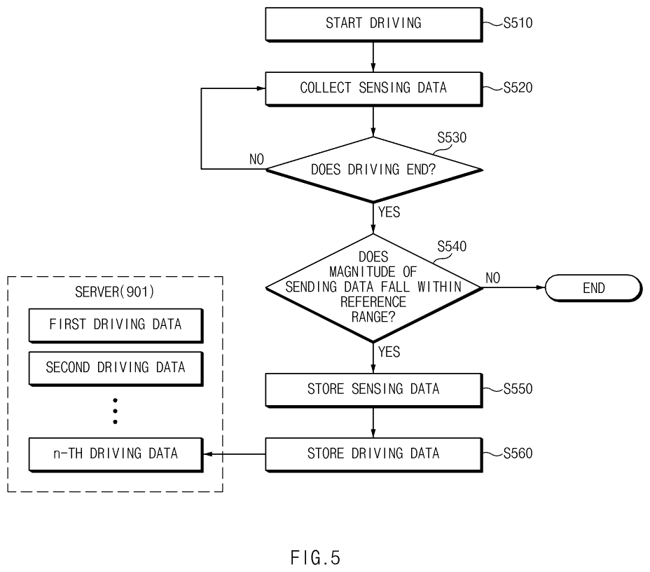

The battery management method, described with reference to FIGS. 5-7, may be performed by at least partially a processor installed in a vehicle and/or at least partially by a processor of a server.

FIG. 5 is a flowchart for describing a method for acquiring driving data according to an embodiment of the present disclosure.

Referring to FIG. 5, in operations S510 and S520, the processor 100 may collect sensing data while the vehicle 1 is driving. The sensing data may include a measured voltage, measured current, and measured temperature of the battery 10.

The processor 100 may acquire sensing data in the unit of a driving-period of the vehicle 1. The driving period may be determined based on an ignition signal of the vehicle. For example, the processor 100 may determine whether the vehicle has begun driving based on the ignition-on signal of the vehicle. The processor 100 may determine whether the vehicle has ended driving based on the ignition-off signal of the vehicle.

The processor 100 may acquire vehicle data via sensors during one driving cycle, that includes a time when the vehicle starts driving and a time when the vehicle ends driving. The acquired vehicle data may correspond to one driving cycle.

In operations S530 and S540, after the vehicle 1 has ended driving, the processor 100 may perform preprocessing to remove abnormal driving data.

The preprocessing may involve a process of removing sensing data that falls outside a predefined reference range. For example, a minimum voltage, a maximum voltage, a minimum current, a maximum current, a minimum temperature, and a maximum temperature may be predefined. The processor 100 may exclude sensing data where a measured voltage is less than the minimum voltage or greater than the maximum voltage and then terminate the process. Similarly, the processor 100 may exclude sensing data where a measured current is less than the minimum current or greater than the maximum current and terminate the process. Furthermore, the processor 100 may exclude sensing data where a measured temperature is lower than the minimum temperature or higher than the maximum temperature and terminate the process.

In an operation S550, when the sensing data falls within the reference range, the processor 100 may associate time information with the sensing data to generate driving data. For example, the processor 100 may generate first driving data based on sensing data collected during a first period and generate second driving data based on sensing data collected during a second period.

The driving data may be stored in a two-dimensional matrix format, such as “N” (number of layers)×“M” (number of sensing data segments). For example, the n-th layer may include the n-th driving data most recently acquired.

In an operation S560, the processor 100 may store the driving data.

The processor 100 may store the driving data in the memory 40 of the vehicle 1.

The processor 100 may store the driving data in the external server 901.

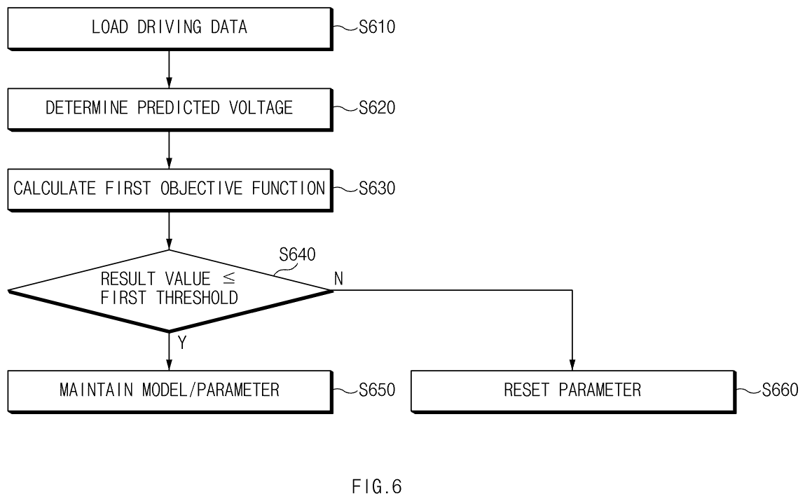

FIG. 6 is a diagram for describing a process for determining the conformity of parameters according to an embodiment of the present disclosure. The process for determining the conformity of parameters may be a process of determining the reliability of the parameters based on the predicted values obtained by the battery model 30 and the sensing data of the battery 10.

Referring to FIG. 6, in an operation S610, the processor 100 may load driving data.

The processor 100 of the vehicle 1 may read driving data stored in the memory 40 or receive driving data from the server 901. Alternatively, the processor of the server 901 may read the driving data stored in the server.

In an operation S620, the processor 100 may determine a predicted voltage.

The processor 100 may identify a measured current included in the driving data and input the measured current value into the battery model 30 to obtain a predicted voltage.

The battery model 30 may determine the predicted voltage of the battery 10 using a parameter that represents the internal state of the battery 10. The battery model 30 may determine the predicted voltage of the battery 10 using the following [Equation 1] to [Equation 5].

$$\frac{\partial {c}_{1 , k}}{\partial t} = {D}_{1 , k}^{eff} \frac{1}{{r}^{2}} \frac{\partial }{\partial r} ( {r}^{2} \frac{\partial {c}_{1 , k}}{\partial r} ) \qquad [ Equation 1 ]$$

Equation 1 is a transport equation that may be used for analyzing the concentration distribution inside solid particles within an electrode, according to an embodiment.

$${ε}_{k} \frac{\partial {c}_{2 , k}}{\partial t} = ∇ \cdot ( {D}_{2 , k}^{eff} ∇ {c}_{2 , k} ) + {a}_{k} ( 1 - {t}_{+} ) {j}_{k} \qquad [ Equation 2 ]$$

Equation 2 is a transport equation that may be used for analyzing the concentration distribution inside the electrolyte within the electrode, according to an embodiment.

$$∇ \cdot ( {σ}_{k}^{eff} ∇ {ϕ}_{1 , k} ) = {a}_{k} {Fj}_{k} \qquad [ Equation 3 ]$$

Equation 3 is a conservation equation that may be used for analyzing the potential distribution among solid particles within the electrode, according to an embodiment.

$$∇ \cdot ( {κ}_{k}^{eff} ∇ {ϕ}_{2 , k} ) - ∇ \cdot [ {κ}_{k}^{eff} \frac{2 R T}{F} ∇ ( ln {c}_{2 , k} ) ] = - {a}_{k} {Fj}_{k} \qquad [ Equation 4 ]$$

Equation 4 is a charge conservation equation that may be for analyzing the potential distribution inside the electrolyte within the electrode, according to an embodiment.

$${j}_{k} = 2 {k}_{k}^{eff} \sqrt{{c}_{2 , k} ( {c}_{1 , k}^{max} - {c}_{1 , k}^{*} ) {c}_{1 , k}^{*}} sinh [ \frac{0.5 R}{FT} {η}_{k} ] \qquad [ Equation 5 ]$$

Equation 5 is the Butler-Volmer equation.

The definitions of the parameters in Equation 1 to Equation 5 are as follows.

The subscripts 1 and 2 may be used to distinguish the states of the parameter. For example, X₁ (X is a certain parameter) may represent the physical quantity inside the solid particle, and X₂ may represent the physical quantity in the liquid state.

Xₖ may be used to distinguish domain areas. For example, when X=p, it may represent the anode domain, when k=s, it may represent the membrane domain, and when k=n, it may represent the cathode domain.

The superscript denoted as t (e.g., X^{t}, X^{t+1}) may indicate time steps.

‘c’ may represent the concentration of lithium ions, ‘c*’ may represent the concentration of lithium ions on the surfaces of the solid particle, and ‘c^{avg}’ may represent the average lithium ion concentration inside the solid particle. ‘Φ’ may represent the potential. ‘j’ may represent the amount of lithium ions per unit volume due to the electrochemical reaction on the surface of the solid particle. ‘Rp’ may represent the radius of the solid particle. ‘D^{eff}’ may represent the diffusion coefficient, and ‘ε’ may represent the porosity. ‘σ^{eff}’ may represent the effective conductivity of the solid, and ‘k^{eff}’ may represent the effective conductivity of the electrolytic cell. ‘A’ may represent the ratio of the activated area of the porous electrode, and ‘t₊’ may represent the yield. ‘F’ may represent the Faraday constant, and ‘R’ may represent the gas constant. ‘T’ may represent the temperature, ‘k’ may represent the reaction rate constant, and ‘R₀’ may represent the internal resistance.

In an operation S630, the processor 100 may calculate a first objective function.

The first objective function is to evaluate a voltage error between a measured voltage of the battery 10 and a predicted voltage obtained by the battery model 30, and may be set in advance. For example, the first objective function (Of1) may use the root mean square error between the measured voltage (V_{meas_i}) (i is a natural number less than or equal to n) and the predicted voltage (V_{sim_i}), as in Equation 6 below.

$$Of 1 = RMS ( {I}_{m e a s} ; ϕ ) = \sqrt{\frac{1}{n} \sum {( {V}_{meas} - {V}_{sim} )}^{2}} \qquad [ Equation 6 ]$$

The predicted voltage (V_{sim_i}) is a predicted voltage obtained based on a predicted current included in the i-th driving data and the measured voltage (V_{meas_i}) may represent a measured voltage included in the i-th driving data.

In an operation S640, the processor 100 may compare the result value of the first objective function with a first threshold.

In an operation S650, when the result value of the first objective function is less than or equal to the first threshold, the processor 100 may maintain the parameter of the battery model 30.

In an operation S660, when the result value of the first objective function exceeds the first threshold, the processor 100 may proceed to a process of resetting parameters.

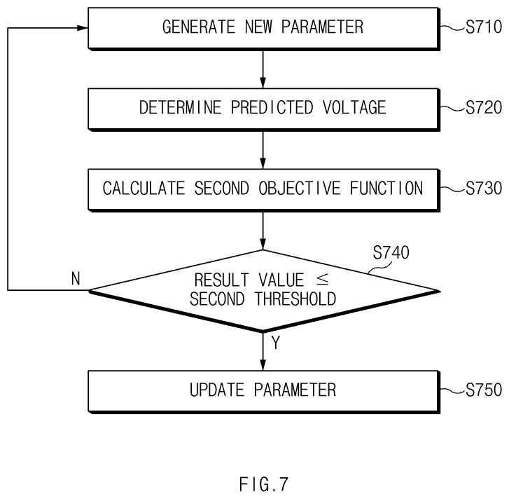

FIG. 7 is a flowchart for describing a process for resetting parameters according to an embodiment of the present disclosure.

Referring to FIG. 7, in an operation S710, the processor 100 may generate a new parameter.

In an operation S720, the processor 100 may determine a predicted voltage using the new parameter. The processor 100 may determine the predicted voltage by inputting a predicted current into the battery model 30 with the new parameter applied.

In an operation S730, the processor 100 may calculate a second objective function.

The second objective function may be used to determine the reliability of the predicted voltage obtained based on the new parameter. The second objective function may use the root mean square error (RMSE) between the measured voltage and the predicted voltage, similarly to the first objective function.

In an operation S740, the processor 100 may compare the result value of the second objective function with a second threshold. The second threshold may be of the same magnitude as the first threshold.

When the result value of the second objective function exceeds the second threshold, the processor 100 may return to the operation S710. In other words, the processor 100 may generate the new parameter again.

In an operation S750, when the result value of the second objective function is less than or equal to the second threshold, the processor 100 may update the parameter. As a result, the battery model 30 may be updated to reflect a parameter capable of reducing the difference between the measured voltage and the predicted voltage to a certain level or lower.

The process for resetting parameters as shown in FIG. 7 may be performed using a genetic algorithm (GA).

The processor 100 of the battery management device 900 according to an embodiment of the present disclosure may obtain state information of the battery 10 using the battery model 30.

The state information of the battery 10 may include at least one of the state of health (SOH), internal resistance, or the loss of active material.

The processor 100 may determine the SOH of the battery 10 based on the ratio of a measured capacity to the initially defined nominal capacity, as shown in Equation 7.

$$SOH = \frac{{Q}_{sim}}{{Q}_{nom}} \qquad [ Equation 7 ]$$

In Equation 7, Qₛᵢₘ may represent a simulated capacity, and Qₙₒₘ may represent the nominal capacity.

The simulated capacity may be determined based on a discharge simulation. For example, the processor 100 may perform discharging until the state of charge (SOC) of the battery 10 reaches to a certain SOC from a SOC of 100 to determine the simulated capacity. The processor 100 may use the following [Equation 8] to determine the simulated capacity.

$${Q}_{sim} = {\int }_{0}^{t} {I}_{applied} d t \qquad [ Equation 8 ]$$

On Equation 8, I_{applied} may represent an applied current.

Among the state information of the battery 10, the loss of active material (LAM) may be obtained based on the following Equation 9.

$$LAM = \frac{{C}_{max}}{{C}_{max , 0}} \qquad [ Equation 9 ]$$

In Equation 9, Cₘₐₓ may represent the theoretical capacity of the active material, and C_{max,0} may represent the initial theoretical capacity.

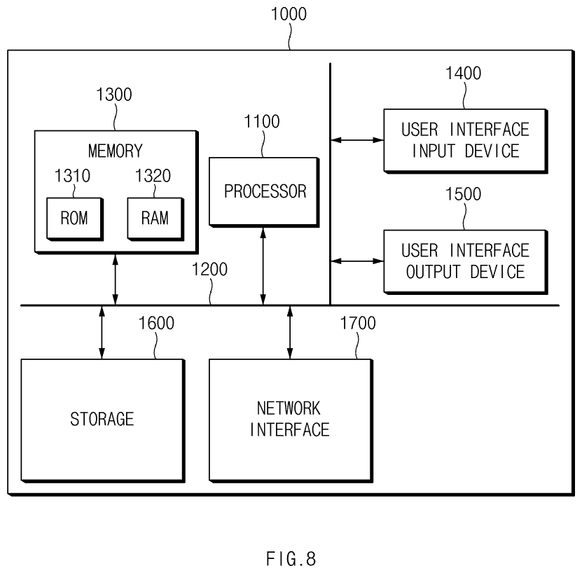

FIG. 8 illustrates a computing system according to an embodiment of the present disclosure.

Referring to FIG. 8, a computing system 1000 may include at least one processor 1100, a memory 1300, a user interface input device 1400, a user interface output device 1500, storage 1600, and a network interface 1700, which are connected with each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read Only Memory (ROM) and a Random Access Memory (RAM).

Thus, the operations of the method or the algorithm described in connection with the embodiments disclosed herein may be embodied directly in hardware or a software module executed by the processor 1100, or in a combination thereof. The software module may reside on a storage medium (e.g., the memory 1300 and/or the storage 1600) such as a RAM, a flash memory, a ROM, an EPROM, an EEPROM, a register, a hard disk, a removable disk, and a CD-ROM.

The storage medium may be coupled to the processor 1100, and the processor 1100 may read information out of the storage medium and may record information in the storage medium. Alternatively, the storage medium may be integrated with the processor 1100. The processor 1100 and the storage medium may reside in an application specific integrated circuit (ASIC). The ASIC may reside within a user terminal. In another case, the processor and the storage medium may reside in the user terminal as separate components.

The above description is merely illustrative of the technical idea of the present disclosure, and various modifications and variations may be made without departing from the essential characteristics of the present disclosure by those having ordinary skill in the art to which the present disclosure pertains.

Accordingly, the embodiments described in the present disclosure are not intended to limit the technical idea of the present disclosure but to describe the present disclosure, and the scope of the technical idea of the present disclosure is not limited by the embodiments. The scope of protection of the present disclosure should be interpreted by the following claims, and all technical ideas within the scope equivalent thereto should be construed as being included in the scope of the present disclosure.

According to an embodiment of the present disclosure, the parameters of the battery model may be updated in real time, thereby increasing the accuracy of the battery model.

Furthermore, according to an embodiment of the present disclosure, the parameters of the battery model may be updated based on driving data of a vehicle equipped with the battery, so that the battery model may be updated by more accurately reflecting the conditions under which the battery is operated.

Furthermore, according to an embodiment of the present disclosure, the state information of the battery may be determined using the battery model that is updated in real time, thereby more accurately acquiring the state information of the battery.

In addition, various effects may be provided that are directly or indirectly understood through the disclosure.

Hereinabove, although the present disclosure has been described with reference to example embodiments and the accompanying drawings, the present disclosure is not limited thereto, but may be variously modified and altered by those having ordinary skill in the art to which the present disclosure pertains without departing from the spirit and scope of the present disclosure claimed in the following claims.

What is claimed is:

1. A battery management device comprising:
a memory configured to store a battery model and an algorithm; and
a processor configured to obtain state information of a battery using the battery model,
wherein the processor is configured to:
obtain a predicted voltage of the battery based on the battery model,
determine a voltage error between a measured voltage of the battery and the predicted voltage, and
update the battery model by resetting a parameter of the battery model based on determining that the voltage error satisfies a threshold condition.

2. The battery management device of claim 1, wherein the parameter is set based on an electrochemical basis to represent internal state information of the battery.

3. The battery management device of claim 1, wherein the processor is configured to:
obtain a measured current of the battery; and
determine the predicted voltage of the battery by inputting the measured current into the battery model.

4. The battery management device of claim 3, wherein the processor is configured to collect the measured current obtained during a driving period of a vehicle equipped with the battery.

5. The battery management device of claim 3, wherein the processor is configured to determine the voltage error based on the measured voltage acquired at same timing as the measured current.

6. The battery management device of claim 5, wherein the processor is configured to determine the voltage error using a root mean square error obtained based on voltage differences between n measured voltages and n predicted voltages, wherein n is a natural number greater than or equal to two.

7. The battery management device of claim 1, wherein the processor is configured to reset the parameter to reduce the voltage error between the measured voltage and the predicted voltage.

8. The battery management device of claim 7, wherein the processor is configured to:
generate a new parameter;
obtain a modified predicted voltage based on the battery model with the new parameter applied; and
reset the parameter such that a voltage error between the measured voltage and the modified predicted voltage falls within a threshold range.

9. The battery management device of claim 8, wherein the processor is configured to reset at least one of an internal resistance, a diffusion coefficient, a reaction rate constant, or a porosity among the parameters.

10. The battery management device of claim 1, wherein the processor is configured to determine at least one of a State Of Health of the battery or a loss of active material using the battery model.

11. A battery management method comprising:
obtaining a predicted voltage of a battery based on a battery model;
determining a voltage error between a measured voltage of the battery and the predicted voltage; and
updating the battery model by resetting a parameter of the battery model based on determining that the voltage error satisfies a threshold condition.

12. The battery management method of claim 11, wherein the parameter is set based on an electrochemical basis to represent internal state information of the battery.

13. The battery management method of claim 11, wherein determining the predicted voltage includes:
obtaining a measured current of the battery; and
inputting the measured current into the battery model.

14. The battery management method of claim 13, wherein obtaining the measured current is performed during a driving period of a vehicle equipped with the battery.

15. The battery management method of claim 13, wherein determining the voltage error includes using the measured voltage acquired at a same timing as the measured current.

16. The battery management method of claim 15, wherein determining the voltage error includes determining a root mean square error based on voltage differences between n measured voltages and n predicted voltages, wherein n is a natural number greater than or equal to two.

17. The battery management method of claim 11, wherein resetting the parameter includes resetting the parameter to reduce the voltage error between the measured voltage and the predicted voltage.

18. The battery management method of claim 17, wherein resetting the parameter includes:
generating a new parameter;
obtaining a modified predicted voltage based on the battery model with the new parameter applied; and
comparing a voltage error between the measured voltage and the modified predicted voltage with a threshold range.

19. A battery management server comprising:
a database configured to store a battery model and an algorithm; and
a processor configured to obtain state information of a battery mounted on a vehicle using the battery model,
wherein the processor is configured to:
collect measured voltage and measured current of the battery obtained during a driving period of the vehicle,
obtain a predicted voltage of the battery based on the battery model,
determine a voltage error between the measured voltage and the predicted voltage, and
update the battery model by resetting a parameter of the battery model based on determining that the voltage error satisfies a threshold condition.

20. The battery management server of claim 19, wherein the processor is configured to:
generate battery state information to include at least one of a State Of Health of the battery or a loss of active material using the battery model; and
transmit the battery state information to the vehicle via a communication device.
